(19) United States
(12) Patent Application Publication
(10) Pub. No.: US 2025/0054882 A1
(43) Pub. Date: Feb. 13, 2025

(54) SEMICONDUCTOR DEVICE WITH AN INDUCTIVE COATING

(71) Applicant: Micron Technology, Inc., Boise, ID (US)

(72) Inventors: Bong Woo Choi, Singapore (SG); Ankur Harish Shah, Singapore (SG)

(21) Appl. No.: 18/788,733

(22) Filed: Jul. 30, 2024

Related U.S. Application Data
(60) Provisional application No. 63/532,178, filed on Aug. 11, 2023.

(51) Int. Cl. H01L 23/60; H01L 23/00

(52) U.S. Cl. CPC H01L 23/60; H01L 24/32; H01L 24/48; H01L 24/73; H01L 24/92; H01L 24/16; H01L 2224/16225; H01L 2224/32225; H01L 2224/48227; H01L 2224/73265; H01L 2224/92247

(57) ABSTRACT

A semiconductor device assembly that includes an inductive coating is disclosed. The semiconductor device assembly includes a semiconductor substrate having circuitry disposed at a first side. A layer of inductive material is disposed at a second side of the semiconductor substrate opposite the first side. A die attach film (DAF) is disposed at the second side of the semiconductor substrate at least partially over the layer of inductive material. The die attach film can be used to attach the semiconductor device assembly to an additional substrate. The layer of inductive material can be disposed at least partially between the semiconductor substrate and the die attach film, which can decrease the damage caused by electrostatic discharge (ESD) events.

### CROSS-REFERENCE TO RELATED APPLICATION(S)

The present application claims priority to U.S. Provisional Patent Application No. 63/532,178, filed Aug. 11, 2023, the disclosure of which is incorporated herein by reference in its entirety.

### TECHNICAL FIELD

The present disclosure generally relates to semiconductor device assemblies and more particularly relates to a semiconductor device with an inductive coating.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIGS. 1A and 1B illustrate simplified schematic cross-sectional views of semiconductor device assemblies in accordance with embodiments of the present technology.

FIGS. 2-4 illustrate simplified schematic cross-sectional views of an example semiconductor device assembly at various fabrication stages.

FIG. 5 illustrates a simplified schematic cross-sectional view of a semiconductor device assembly in accordance with an embodiment of the present technology.

FIG. 6 illustrates a schematic view of a system that includes a semiconductor device assembly configured in accordance with an embodiment of the present technology.

FIG. 7 illustrates a method of fabricating a semiconductor device assembly in accordance with an embodiment of the present technology.

### DETAILED DESCRIPTION

A semiconductor device assembly is fabricated through various steps of material deposition and removal. The semiconductor device assembly can include a semiconductor substrate on which circuitry (e.g., traces, lines, vias, diodes, transistors, and other electrical components) is disposed to implement a functional semiconductor die. Various steps of the assembly process can result in friction at the semiconductor substrate, which can result in charge accumulation. Similarly, the various pastes and other materials to which the semiconductor substrate is exposed during the assembly process can transfer charge to the semiconductor substrate. This charge can continue to build up until the charge surpasses the storage capacity of the semiconductor substrate, at which point an electrostatic discharge (ESD) event can occur where the charge is released from the semiconductor substrate. The release of the charge from the semiconductor substrate can cause a sudden large peak current to flow through the circuitry. This sudden peak current, or a resulting increase in temperature, can damage the circuitry, thereby reducing the yield or the durability of the semiconductor device assembly.

Various techniques are used to reduce the accumulation of charge in a semiconductor device assembly. For example, ionizer fans and other tools can be used to discharge the semiconductor substrate. The operation time required to sufficiently discharge the semiconductor substrate using these tools can be overly burdensome on the assembly process, reducing efficiency and increasing cost. In other cases, improved indirect materials (IDMs), such as back grinding tapes, die attach films (DAFs), and dicing tapes that reduce the accumulation of charge on the semiconductor substrate can be used during the assembly process. These improved IDMs can come at an increased cost and their effectiveness can depend on the external vendors that provide these products, thereby increasing cost and adding unpredictability to the assembly process.

To address these drawbacks and others, embodiments of the present technology relate to a semiconductor device assembly with an inductive coating, which can be applied directly to the backside of the semiconductor substrate to reduce the accumulation of charge thereat by enabling the charge to dissipate or reducing electron transfer to the semiconductor substrate. The inductive coating can be applied as part of the thinning cycle of the assembly process. Thus, the inductive coating can be applied with minimal added cost or assembly time. The inductive coating can be applied before performing some of the assembly operations, such as die attach operations and dicing operations, thereby reducing the risk of charge accumulation during these processes. In doing so, cost-sensitive IDMs without ESD risk mitigation features can be used for assembly. The inductive coating can be applied with a thickness less than 100 nanometers, which can reduce the impact of the coating on substrate roughness to limit DAF adhesion and wettability concerns. In this way, the inductive coating can be added with minimal effect on device thickness and yield.

### Example Semiconductor Device Assembly

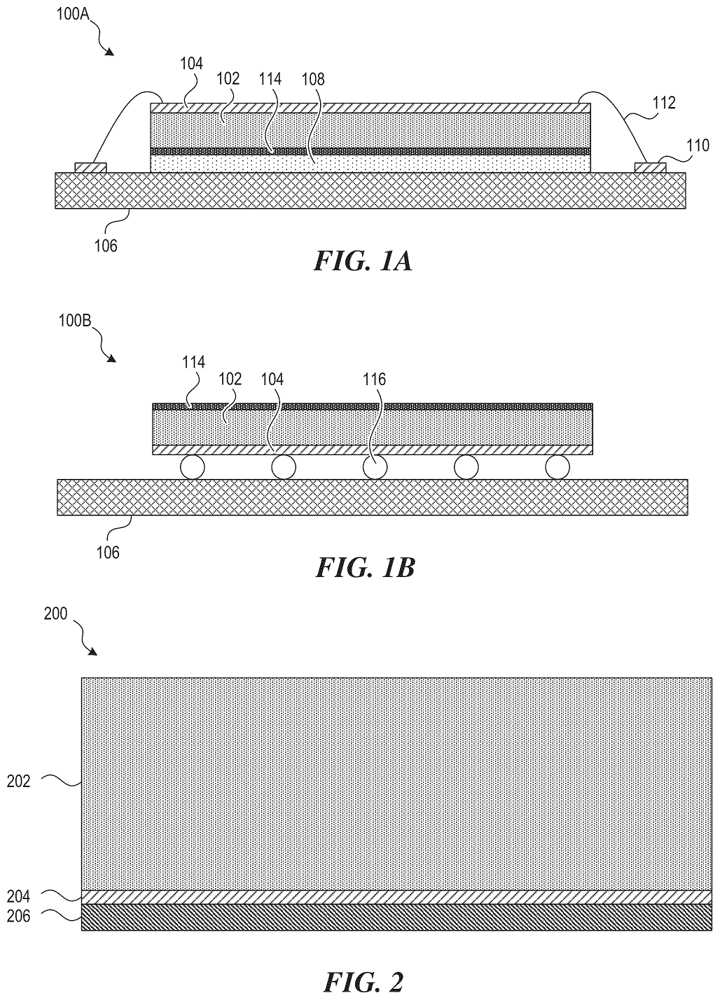

FIG. 1A illustrates a simplified schematic cross-sectional view of a semiconductor device assembly 100A in accordance with an embodiment of the present technology. The semiconductor device assembly 100A includes a semiconductor substrate 102 having circuitry 104 (e.g., diodes, transistors, traces, lines, vias, and other electrical components) disposed at a first side (e.g., a front side) to implement a semiconductor die. The semiconductor substrate 102 can attach to a substrate 106 (e.g., a package-level substrate, motherboard, interposer, or printed circuit board (PCB)) through a DAF 108 at a second side of the semiconductor substrate 102 opposite the first side. The substrate 106 can include one or more contact pads 110 that couple to one or more circuit components (e.g., power, ground, processors, memory, or other components on a motherboard) through internal or external electrical components (e.g., traces, lines, vias, and solder balls). Although not illustrated, one or more contact pads can be disposed at the first side of the semiconductor substrate 102 and coupled with the circuitry 104. The contact pads at the semiconductor substrate 102 can electrically (e.g., and mechanically) couple with the contact pads 110 on the substrate 106 through interconnects (e.g., wires 112) to provide functionality (e.g., power, ground, input/output (I/O) signaling) to the circuitry 104 through the substrate 106.

A layer of inductive material 114 can be disposed at the second side of the semiconductor substrate 102. The inductive material 114 can reduce the accumulation of charge on the second side of the semiconductor substrate 102 to limit the risk of ESD events. For example, the inductive material 114 can have inductive properties that enable charge to be dissipated slowly from the semiconductor substrate 102. The slow dissipation of charge from the semiconductor substrate 102 can reduce the accumulation of charge on the semiconductor substrate 102, which can limit the occurrence of ESD events where charge is quickly dissipated through a high peak current. In aspects, the inductive material 114 can oppose the movement of electrons to the semiconductor substrate 102. The inductive material 114 can increase the resistance to an accumulation of charge at the semiconductor substrate 102 resulting from the semiconductor substrate 102 experiencing friction or contacting assembly materials during the assembly process.

The layer of inductive material 114 can include any material having inductive properties. For example, the inductive material 114 can include an inductive polymer, such as Polyaniline, Polypyrrole, or Polyamidoamin. The inductive material 114 can include an insulating material with additives of conductive material. For example, the insulating material can include a polymer, and the conductive material can include nanoparticles of conductive material (e.g., gold, silver, copper, aluminum, tin), nanoparticles or carbon nanotubes.

As a specific example, the layer of inductive material 114 includes Polyaniline. The Polyaniline is disposed between the semiconductor substrate 102 and the DAF 108. The DAF 108 can be used to attach the semiconductor substrate 102 to a substrate 106. The substrate 106 can include contact pads 110 coupling with circuitry 104 at the semiconductor substrate 102 through wires 112.

As illustrated, the layer of inductive material 114 is disposed at least partially between the semiconductor substrate 102 and the DAF 108. In some embodiments, the layer of inductive material 114 can extend across the entire surface of the second side of the semiconductor substrate 102. The DAF 108 can be at least partially disposed over the layer of inductive material 114. In some cases, the layer of inductive material 114 can be a thin coating, e.g., having a thickness less than 100 nanometers, less than 50 nanometers, between 5 and 50 nanometers, and so on. Given that the layer of inductive material 114 can be relatively thin (e.g., less than 100 nanometers, less than 50 nanometers, less than 25 nanometers), the layer of inductive material 114 can have a minimal impact on the surface roughness of the semiconductor substrate 102. Surface roughness can impact the adhesion of the DAF 108 to the semiconductor substrate 102 or the wettability of the DAF 108 during die attach. Accordingly, the layer of inductive material 114 can be applied with limited effect to DAF adhesion or wettability. Moreover, given the thinness of the layer of inductive material 114, the inductive material 114 can have minimal effect on the overall thickness of the semiconductor device assembly 100A and can thus be implemented even in size-constrained devices.

Although illustrated in a single-die, wire-bonded configuration, the inductive coating can be implemented in semiconductor devices with one or more semiconductor dies arranged in different configurations. For example, the semiconductor devices can include a stack of semiconductor dies attached through DAF and wire-bonded to the substrate. One or more of the semiconductor dies can include a layer of inductive material. In some embodiments, the semiconductor device can include a single flip-chip die with a layer of inductive material or multiple stacked dies with one or more of the stacked dies having a layer of inductive material. In aspects, the semiconductor device can include one or more additional dies attached through a DAF to a flip-chip die, where one or more of the dies can include a layer of inductive material. It is appreciated that these are just some of the possible embodiments and that a layer of inductive material can be implemented within any number of semiconductor devices to reduce the risk of ESD events.

In yet another aspect, the semiconductor device assembly 100B can be arranged in a flip-chip configuration, as illustrated in FIG. 1B. For example, the semiconductor substrate 102 can include circuitry 104 at a front side. Interconnects 116 (e.g., solder balls) can couple with the contact pads within the circuitry 104 and contact pads on the substrate 106 to electrically and mechanically couple the circuitry 104 and the substrate 106. Similar to the semiconductor device assembly 100A, the semiconductor device assembly 100B includes the layer of inductive material 114 disposed at the back side of the semiconductor substrate 102 opposite the substrate 106. The layer of inductive material 114 can reduce the occurrence of or the damage caused by ESD events.

FIGS. 2-4 illustrate simplified schematic cross-sectional views of an example semiconductor device assembly at various fabrication stages. The operations can be performed at the wafer-level or the die-level. Although illustrated in a particular configuration, the various fabrication stages can be omitted, repeated, or reorganized. Moreover, the fabrication stages can include one or more additional stages not illustrated in FIGS. 2-4.

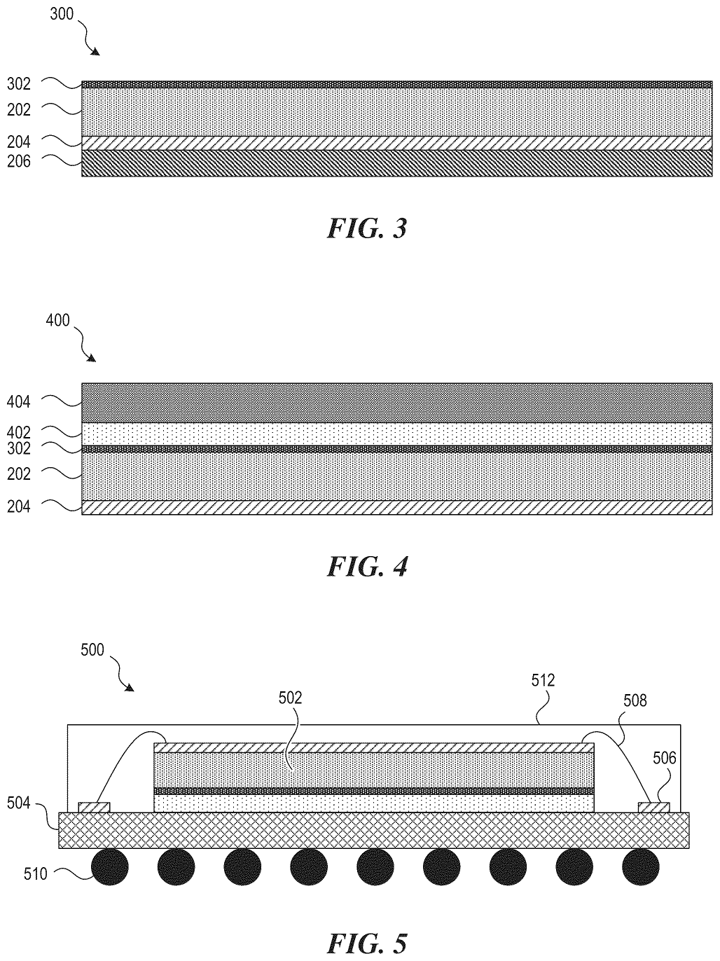

Beginning with FIG. 2, a semiconductor device assembly is illustrated at stage 200 where a semiconductor substrate 202 (e.g., semiconductor wafer) is provided. Circuitry 204 (e.g., diodes, transistors, traces, lines, vias, and other electrical components) is disposed at a front side of the semiconductor substrate 202 to implement one or more semiconductor dies. Once the circuitry 204 has been disposed on the semiconductor substrate 202, the semiconductor substrate 202 may be attached to back grinding tape 206 or a carrier substrate (e.g., wafer) at the front side to support the semiconductor substrate 202 during processing. When attached to the back grinding tape 206, the back side (e.g., opposite the circuitry 204) of the semiconductor substrate 202 can be exposed for thinning, as illustrated in FIG. 3.

Continuing to FIG. 3, the semiconductor device assembly is illustrated at a stage 300 where the semiconductor substrate 202 is thinned at the back side (e.g., opposite the circuitry 204 and the back grinding tape 206) and a layer of inductive material 302 is disposed. The semiconductor substrate 202 can be thinned such that the thickness of the semiconductor device assembly satisfies spatial requirements. For example, the semiconductor substrate 202 may be thinned such that the total thickness of the semiconductor device assembly is less than 25 microns, 30 microns, 35 microns, 40 microns, 50 microns, 75 microns, 100 microns, or the like. The semiconductor substrate 202 can be thinned through grinding, etching, polishing, planarization (e.g., chemical-mechanical planarization (CMP)), or any other appropriate method. In aspects, the layer of inductive material 302 can be deposited during the thinning cycle. For example, the layer of inductive material 302 can be disposed after the back grinding process. In some embodiments, the layer of inductive material 302 can be deposited after a fine polishing process. The layer of inductive material 302 can be disposed before a dry polish process. In aspects, the layer of inductive material 302 can be disposed in combination with another process (e.g., during a wafer wash/dry process). For example, the inductive material 302 can be included within a solvent or polish applied to the semiconductor substrate 202. As a result, the layer of inductive material 302 can be disposed with minimal impact to the fabrication time.

The layer of inductive material 302 can be deposited through any appropriate method. For example, the layer of inductive material 302 can be deposited through spin coating, spray coating, chemical wash, dispensing, chemical vapor deposition (CVD), physical vapor deposition (PVD), or any other technique. As a specific example, the layer of inductive material 302 can include Polyaniline and can be deposited on the semiconductor substrate 202 using CVD. In some cases, the layer of inductive material 302 is deposited through a chemical-level process to reduce the impact of the layer of inductive material 302 on future processing steps. The layer of inductive material 302 can be deposited in a thin layer. For example, the layer of inductive material 302 can have a thickness less than 100 nanometers, less than 50 nanometers, or between 5 and 50 nanometers to limit the impact of the inductive material 302 on surface roughness. In doing so, DAF adhesion and DAF wettability concerns can be limited. Moreover, overall semiconductor device assembly thickness can be minimized. After thinning, the back grinding tape 206 can be removed. A DAF and dicing tape can then be disposed at the semiconductor substrate 202, and the semiconductor substrate 202 can be diced, as illustrated in FIG. 4.

Continuing at FIG. 4, the semiconductor device assembly is illustrated at a stage 400 where a DAF 402 and dicing tape 404 are attached to the semiconductor substrate 202 at the back side and the semiconductor substrate 202 is diced. The DAF 402 can be disposed at the back side of the semiconductor substrate 202 at least partially over the layer of inductive material 302. Dicing tape 404 can then be disposed at the back side of the semiconductor substrate 202 at least partially over the DAF 402. Once the dicing tape 404 is attached, the semiconductor substrate 202 can be diced at the front side (e.g., at the circuitry 204) to singulate the semiconductor dies implemented on the semiconductor substrate 202. The singulated semiconductor dies can then be removed from the dicing tape 404 and attached to an additional substrate (e.g., a package-level substrate, an additional semiconductor die) through the DAF 402. Interconnects (e.g., wires) can then be formed between contact pads (not shown) on the semiconductor die and contact pads on the additional substrate. An example of a resulting semiconductor device assembly is illustrated in FIG. 5.

FIG. 5 illustrates a simplified schematic cross-sectional view of a semiconductor device assembly 500 in accordance with an embodiment of the present technology. A semiconductor die 502 (e.g., in accordance with an embodiment of the present technology) is coupled with a substrate 504 in a wire-bonded configuration. Although illustrated as including a single, wire-bonded semiconductor die, the semiconductor device assembly 500 can include one or more semiconductor dies arranged in a same or different arrangement (e.g., a flip-chip arrangement, a hybrid flip-chip, wire-bonded arrangement). The substrate 504 can be a singulated substrate in accordance with one or more embodiments described herein. For example, the semiconductor die 502 can be coupled with a panel-level or strip-level substrate that is sawed to singulate the substrate 504 and the semiconductor die 502.

The semiconductor die 502 can include contact pads (not shown) at the front side that connect to a metallization layer (e.g., through traces, lines, vias, or other connection structures). The substrate 504 can similarly include contact pads 506 at an upper surface. Interconnects (e.g., wires 508) can be formed between the contact pads on the semiconductor die 502 and the contact pads 506 on the substrate 504 to electrically couple the semiconductor die 502 and the substrate 504. The substrate 504 can include various circuitry (e.g., traces, lines, vias, or other connection structures) between the contact pads 506 at the upper surface and contact pads at a lower side of the substrate 504 at which connective structures 510 (e.g., solder balls) are disposed. In this way, external connectivity (e.g., power, ground, and I/O signaling) can be provided through the connective structures 510. The semiconductor device assembly 500 can further include an encapsulant material 512 (e.g., mold resin compound) that at least partially encapsulates the semiconductor die 502 and the substrate 504 to prevent electrical contact therewith or provide mechanical strength to the semiconductor device assembly 500.

In accordance with one aspect of the present disclosure, the semiconductor devices illustrated in the assemblies of FIGS. 1A-5 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.) or a mix of logic and memory dies (e.g., a memory controller die and a memory die controlled thereby).

In one embodiment, the semiconductor device assemblies of FIGS. 1A-5 can include one or more logic dies (e.g., controllers). For example, logic dies can have a higher risk of ESD events. Accordingly, the layer of inductive material can be implemented only on the logic dies within a semiconductor assembly or on the logic dies and other dies within the semiconductor device assembly.

### Example Systems

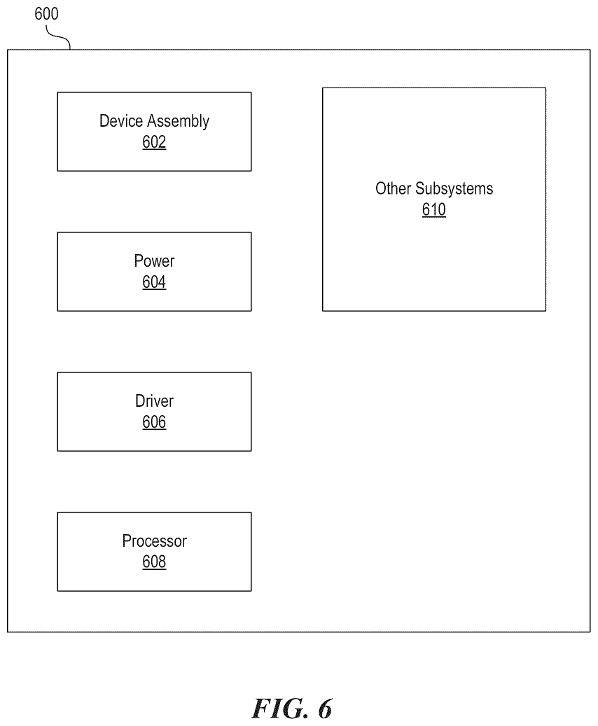

Any one of the semiconductor devices and semiconductor device assemblies described above with reference to FIGS. 1A-5 can be incorporated into any of a myriad of larger and/or more complex systems, a representative example of which is system 600 shown schematically in FIG. 6. The system 600 can include a semiconductor device assembly 602 (e.g., a discrete semiconductor device), a power source 604, a driver 606, a processor 608, and/or other subsystems or components 610. The semiconductor device assembly 602 can include features generally similar to those of the semiconductor device assemblies described above with reference to FIGS. 1A-5. The resulting system 600 can perform any of a wide variety of functions, such as memory storage, data processing, and/or other suitable functions. Accordingly, representative system 600 can include, without limitation, hand-held devices (e.g., mobile phones, tablets, digital readers, and digital audio players), computers, vehicles, appliances, and other products. Components of the system 600 can be housed in a single unit or distributed over multiple, interconnected units (e.g., through a communications network). The components of the system 600 can also include remote devices and any of a wide variety of computer-readable media.

### Example Methods

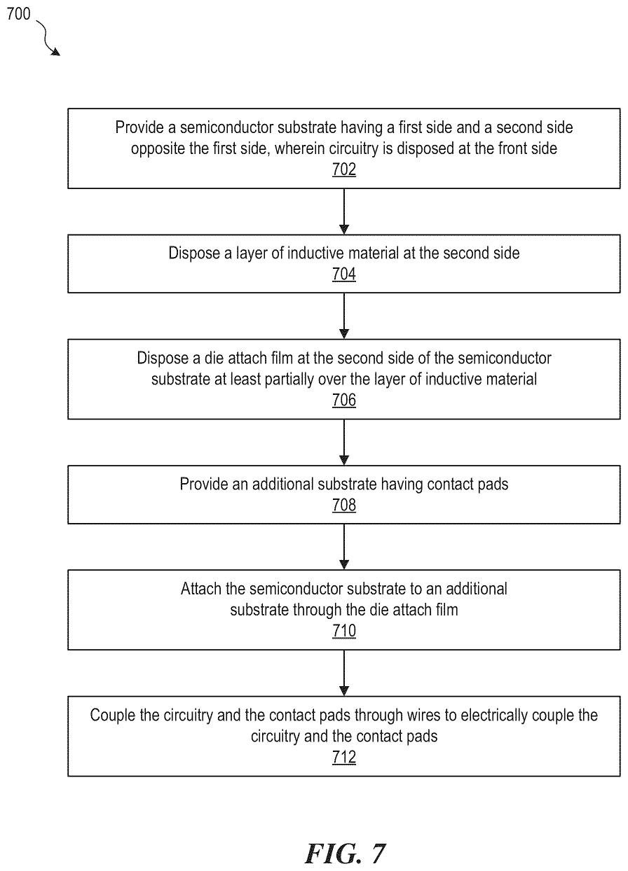

FIG. 7 illustrates a method 700 for fabricating a semiconductor device assembly. Although illustrated in a particular configuration, operations within any of the methods may be omitted, repeated, or reorganized. Moreover, any of the methods may include additional operations, for example, those detailed in one or more other methods described herein. At 702, a semiconductor substrate is provided. The substrate has a first side and a second side opposite the first side, and circuitry is disposed at the first side. At 704, a layer of inductive material is disposed at the second side. At 706, a DAF is disposed at the second side of the semiconductor substrate at least partially over the layer of inductive material. At 708, an additional substrate is provided. The additional substrate has contact pads. At 710, the semiconductor substrate is attached to an additional substrate through the DAF. At 712, the circuitry and the contact pads are electrically coupled through wires. In doing so, an ESD-resistant semiconductor device assembly can be fabricated.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using CVD, PVD, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3DI) applications.

The devices discussed herein, including a memory device, can be formed on a semiconductor substrate or die, such as silicon, germanium, silicon-germanium alloy, gallium arsenide, gallium nitride, etc. In some cases, the substrate is a semiconductor wafer. In other cases, the substrate can be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, can be controlled through doping using various chemical species including, but not limited to, phosphorous, boron, or arsenic. Doping can be performed during the initial formation or growth of the substrate, by ion-implantation, or by any other doping means.

The functions described herein can be implemented in hardware, software executed by a processor, firmware, or any combination thereof. Other examples and implementations are within the scope of the disclosure and appended claims. Features implementing functions can also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications can be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly comprising:
a semiconductor substrate having a first side and a second side opposite the first side;
circuitry disposed at the first side of the semiconductor substrate;
a layer of inductive material disposed at the second side of the semiconductor substrate; and
a die attach film disposed at the second side of the semiconductor substrate such that the layer of inductive material at least partially separates the die attach film and the semiconductor substrate.

2. The semiconductor device assembly of claim 1, wherein the layer of inductive material includes an inductive polymer.

3. The semiconductor device assembly of claim 1, wherein the layer of inductive material includes an insulating material having an additive of conductive material.

4. The semiconductor device assembly of claim 3, wherein the conductive material comprises carbon nanotubes or gold nanoparticles.

5. The semiconductor device assembly of claim 1, wherein the layer of inductive material has a thickness less than 50 nanometers.

6. The semiconductor device assembly of claim 1, further comprising one or more contact pads disposed at the first side and electrically coupled with the circuitry.

7. A method of fabricating a semiconductor device assembly comprising:
providing a semiconductor substrate having a first side and a second side opposite the first side, wherein circuitry is disposed at the first side;
disposing a layer of inductive material at the second side;
disposing a die attach film at the second side of the semiconductor substrate at least partially over the layer of inductive material;
providing an additional substrate having contact pads;
attaching the semiconductor substrate to an additional substrate through the die attach film; and
coupling the circuitry and the contact pads through wires to electrically couple the circuitry and the contact pads.

8. The method of claim 7, further comprising:
attaching the semiconductor substrate to a back grinding tape at the first side; and
responsive to attaching the semiconductor substrate to the back grinding tape, thinning the semiconductor substrate at the second side,
wherein the layer of inductive material is disposed at the second side of the semiconductor substrate responsive to thinning the semiconductor substrate at the second side.

9. The method of claim 8, wherein disposing the layer of inductive material and thinning the semiconductor substrate are performed during a same processing step.

10. The method of claim 7, further comprising:
attaching the semiconductor substrate to dicing tape at the second side; and
responsive to attaching the semiconductor substrate to the dicing tape, dicing the semiconductor substrate,
wherein the semiconductor substrate is attached to the additional substrate responsive to dicing the semiconductor substrate.

11. The method of claim 7, further comprising disposing the layer of inductive material using spin coating, spray coating, or chemical treatment.

12. The method of claim 7, further comprising disposing the layer of inductive material with a thickness less than 50 nanometers.

13. The method of claim 7, wherein the layer of inductive material comprises an insulating material with an additive of conductive material.

14. A semiconductor device assembly comprising:
a semiconductor substrate having a first side and a second side opposite the first side;
circuitry disposed at the first side of the semiconductor substrate, the circuitry including a first contact pad;
a layer of inductive material disposed at the second side of the semiconductor substrate;
a die attach film disposed at the second side of the semiconductor substrate at least partially over the layer of inductive material;
an additional substrate having a second contact pad, the semiconductor substrate attached to the additional substrate through the die attach film; and
a wire electrically coupling the first contact pad and the second contact pad.

15. The semiconductor device assembly of claim 14, wherein the layer of inductive material comprises an insulated material with an additive of conductive material.

16. The semiconductor device assembly of claim 15, wherein the conductive material comprises carbon nanotubes or gold nanoparticles.

17. The semiconductor device assembly of claim 14, wherein the layer of inductive material includes an inductive polymer.

18. The semiconductor device assembly of claim 14, wherein the layer of inductive material has a thickness less than 50 nanometers.

19. The semiconductor device assembly of claim 14, further comprising:
an additional semiconductor substrate having a third side and a fourth side opposite the third side;
additional circuitry disposed at the third side of the additional semiconductor substrate, the circuitry including a third contact pad;
an additional layer of inductive material disposed at a fourth side of the additional semiconductor substrate opposite the third side;
an additional die attach film disposed at the second side of the additional semiconductor substrate at least partially over the additional layer of inductive material;
a fourth contact pad disposed at the additional substrate; and
an additional wire electrically coupling the third contact pad and the fourth contact pad,
wherein the additional semiconductor substrate attaches to the semiconductor substrate through the additional die attach film.

20. The semiconductor device assembly of claim 14, wherein the semiconductor device assembly comprises a NOT-AND (NAND) memory device or a dynamic random access memory (DRAM) device.
